(19) United States
(12) Patent Application Publication
(10) Pub. No.: US 2026/0314182 A1
(43) Pub. Date: Oct. 8, 2026

(54) DISPLAY PANEL AND PREPARATION METHOD THEREFOR, AND DISPLAY DEVICE

(71) Applicant: Hefei Visionox Technology Co., Ltd., Hefei (CN)

(72) Inventors: Zhiwei ZHOU, Hefei (CN); Jinfang ZHANG, Hefei (CN)

(73) Assignee: Hefei Visionox Technology Co., Ltd., Hefei (CN)

(21) Appl. No.: 19/420,741

(22) Filed: Dec. 16, 2025

(30) Foreign Application Priority Data
Feb. 6, 2025 (CN) 202510134494.0

(51) Int. Cl. H10K 59/122; H10K 59/12

(52) U.S. Cl. CPC H10K 59/122; H10K 59/1201

(57) ABSTRACT

The present disclosure provides a display panel and a preparation method therefor, and a display device. The display panel includes a substrate, and an isolation structure and a plurality of light-emitting devices located on the substrate. The isolation structure defines at least one light-transmitting opening and a plurality of isolation openings, the light-emitting devices are at least partially located inside the isolation openings, the isolation structure includes a support portion and an isolation portion that are stacked, a distance by which the isolation portion extends beyond the support portion is defined as a first spacing, and the first spacing located inside the light-transmitting opening is greater than the first spacing located inside the isolation opening.

### CROSS-REFERENCE TO RELATED APPLICATIONS

The present application claims priority to the Chinese Patent Application 202510134494.0, filed on Feb. 6, 2025, and the entire contents of the aforementioned application are hereby incorporated by reference in its entirety.

### FIELD

The present disclosure relates to the field of display, and in particular to a display panel and a preparation method therefor, and a display device.

### BACKGROUND

An organic light-emitting diode (OLED) is an organic thin-film electroluminescent device, which has received great attention and has been widely used in electronic display products thanks to its advantages such as simple preparation process, low cost, low power consumption, high luminance, wide angle of view, high contrast, and enabling flexible display. During the preparation of conventional display panels, light-emitting pixel patterning is usually implemented by means of a fine metal mask (FMM). FMM technology is mature and has rich experience in mass production. However, FMM technology also has problems such as limited accuracy, high development costs, and long development cycle. Fine metal mask-free technology eliminates the limitations of conventional OLED processes on display size, resolution, and other screen performances, and has the advantages of high performance, full-size coverage, and agile delivery. Patents CN118251982A, CN115666161A, CN116648095A, CN117062489A, CN118678742A, CN118785761A, CN115224220A, CN118678729A, CN118660529A and CN118660589A describe contents related to the fine metal mask-free technology for reference.

However, due to the limitations of their own structural designs, it is difficult for current electronic display products to improve the light transmittance while ensuring a high pixel density when applied to scenarios such as under-display recognition and transparent display.

### SUMMARY

A first aspect of the present disclosure provides a display panel. The display panel includes a substrate, and an isolation structure and a plurality of light-emitting devices located on the substrate. The isolation structure defines at least one light-transmitting opening and a plurality of isolation openings, the light-emitting devices are at least partially located inside the isolation openings, the isolation structure includes a support portion and an isolation portion arranged on the support portion, a distance by which the isolation portion extends along and beyond an edge of the support portion is defined as a first spacing, and the first spacing located inside the light-transmitting opening is greater than the first spacing located inside the isolation opening.

In the above embodiments, by increasing the first spacing at the light-transmitting opening, light with a larger tilt angle can pass through the light-transmitting opening, thereby increasing the light transmittance of the display panel without affecting the arrangements (area, arrangement density, etc.) of the isolation openings.

In a specific implementation of the first aspect of the present disclosure, an orthographic projection of a surface of the support portion away from the substrate on the substrate is located within an orthographic projection of a surface of the isolation portion close to the substrate on the substrate, and a distance between adjacent edges of the two orthographic projections is the first spacing.

In a specific implementation of the first aspect of the present disclosure, an orthographic projection of the support portion on the substrate is located within an orthographic projection of the isolation portion on the substrate, a distance between adjacent edges of the two orthographic projections is defined as a second spacing, and the second spacing located inside the light-transmitting opening is greater than the second spacing located inside the isolation opening.

In a specific implementation of the first aspect of the present disclosure, each light-emitting device includes a first electrode, a light-emitting functional layer and a second electrode sequentially stacked on the substrate, the light-emitting functional layer and the second electrode being at least partially located in the corresponding isolation opening, a plurality of first electrodes being spaced apart from each other, and the light-transmitting opening being arranged between every two adjacent first electrodes. In a specific implementation of the first aspect of the present disclosure, the support portion is of a conductive structure, and the second electrode is connected to the support portion. In this way, the isolation structure connects second electrodes of the light-emitting devices to form a common electrode.

In a specific implementation of the first aspect of the present disclosure, the support portion further includes a body portion and a bottom portion, the bottom portion being located between the body portion and the substrate.

In a specific implementation of the first aspect of the present disclosure, an orthographic projection of the bottom portion on the substrate is located within the orthographic projection of the isolation portion on the substrate, and an orthographic projection of the body portion on the substrate is located within the orthographic projection of the bottom portion on the substrate. For example, in the isolation opening, a spacing between an orthographic projection of an edge of the bottom portion on the substrate and an orthographic projection of an edge of the isolation portion on the substrate is the second spacing.

In the above embodiments, the second electrode is more easily deposited on the bottom portion compared a side surface of the body portion, and therefore, the provision of the bottom portion can reduce impedance at the connection of the second electrode and the isolation structure.

In another specific implementation of the first aspect of the present disclosure, the support portion includes a body portion and a bottom portion located on a side of the body portion away from the isolation portion, and an orthographic projection of the bottom portion on the substrate is located within the orthographic projection of the isolation portion on the substrate. In the isolation opening, an orthographic projection of an edge of the body portion on the substrate is located within the orthographic projection of the bottom portion on the substrate, and in the isolation opening, a spacing between an orthographic projection of an edge of the bottom portion on the substrate and an orthographic projection of an edge of the isolation portion on the substrate is the second spacing, that is, the spacing between the orthographic projection of the edge of the bottom portion on the substrate and the orthographic projection of the edge of the isolation portion on the substrate is the second spacing. In the light-transmitting opening, the orthographic projection of the edge of the bottom portion on the substrate coincides with the orthographic projection of the body portion on the substrate, or the orthographic projection of the edge of the bottom portion on the substrate is located within the orthographic projection of the body portion on the substrate, and a spacing between an orthographic projection of an edge of the body portion facing an end of the bottom portion on the substrate and the orthographic projection of the edge of the isolation portion on the substrate is the second spacing. For example, a distance between adjacent edges of the orthographic projections of the body portion and the isolation portion is defined as a third spacing. In one embodiment,, the third spacing located inside the light-transmitting opening is greater than or equal to the third spacing located inside the isolation opening.

In the above embodiments, in the isolation opening, the second electrode is more easily deposited on the bottom portion than on the side surface of the body portion, and therefore, the provision of the bottom portion can reduce impedance at the connection of the second electrode and the isolation structure. Furthermore, compared with the side of the isolation opening, part of the bottom portion that is located on the side of the light-transmitting opening is removed, and the bottom portion may not shield an edge region of the light-transmitting opening, thereby increasing the size of the first spacing at the light-transmitting opening, and thus further increasing the transmittance of light with a large tilt angle at the light-transmitting opening.

In a specific implementation of the first aspect of the present disclosure, materials of the bottom portion, the body portion and the isolation portion have sequentially increasing etch resistance. In this way, the bottom portion at the lowermost layer can be etched during an etching process (for example, wet etching), and the bottom portion is laterally etched at the light-transmitting opening, thereby being shielded by the body portion.

In a specific implementation of the first aspect of the present disclosure, materials of the bottom portion, the body portion and the isolation portion are molybdenum, aluminum and titanium, respectively.

In a specific implementation of the first aspect of the present disclosure, the display panel may further include a pixel defining layer, the pixel defining layer is located between the isolation structure and the substrate, the pixel defining layer includes a plurality of pixel openings corresponding to the isolation openings, and the pixel openings are in communication with the corresponding isolation openings. The first electrode is located between the pixel defining layer and the substrate, and each pixel opening is configured to confine the light-emitting device and expose the first electrode.

In a specific implementation of the first aspect of the present disclosure, the pixel openings correspond to the isolation openings on a one-to-one basis, and an orthographic projection of the light-transmitting opening on the substrate is located within an orthographic projection of the pixel defining layer on the substrate.

In one embodiment,, the pixel defining layer is an inorganic film layer.

In a specific implementation of the first aspect of the present disclosure, the display panel may further include a first encapsulation layer, where the first encapsulation layer is located on a side of a light-emitting device away from the substrate and includes a plurality of encapsulation units corresponding to the isolation openings on a one-to-one basis, and the encapsulation units cover the corresponding isolation openings.

In a specific implementation of the first aspect of the present disclosure, an edge of an encapsulation unit extends to a side of the isolation structure (e.g., the isolation portion included therein) away from the substrate, and part of the encapsulation unit located on the side of the isolation structure (e.g., the isolation portion included therein) away from the substrate is spaced apart from the isolation structure (e.g., the isolation portion included therein) to form a suspended portion.

In a specific implementation of the first aspect of the present disclosure, the plurality of light-emitting devices are classified into multiple types of light-emitting devices that emit different colors of light, and the encapsulation units that respectively correspond to the light-emitting devices that emit different colors of light and are adjacent to each other are spaced apart from each other.

In a specific implementation of the first aspect of the present disclosure, the display panel may further include a second encapsulation layer and a third encapsulation layer that cover the first encapsulation layer and the isolation structure, and the second encapsulation layer is located between the first encapsulation layer and the third encapsulation layer.

In one embodiment,, the first encapsulation layer and the third encapsulation layer are inorganic layers, and the second encapsulation layer is an organic layer; and in one embodiment,, the second encapsulation layer serves as a planarization layer.

In a specific implementation of the first aspect of the present disclosure, the display panel may further include an active area, the active area includes a first region and a second region, the second region is located on at least one side of the first region, the first region has a higher light transmittance than the second region, and the light-transmitting opening is located in the first region.

A second aspect of the present disclosure provides a preparation method for a display panel. The preparation method includes: providing a substrate; forming a plurality of first electrodes on the substrate; forming an isolation structure on a side of the substrate, where the isolation structure is formed with at least one light-transmitting opening and a plurality of isolation openings, the isolation structure includes a support portion facing the substrate and an isolation portion away from the substrate, a distance by which the isolation portion extends along and beyond an edge of the support portion is defined as a first spacing, and the first spacing located inside the light-transmitting opening is greater than the first spacing located inside an isolation opening; and forming a light-emitting functional layer and a second electrode in each of the isolation openings, where a first electrode, the light-emitting functional layer and the second electrode stacked at each isolation opening form a light-emitting device; where the first spacing at the isolation opening is less than the first spacing at the light-transmitting opening after all the light-emitting devices are formed.

In the display panel obtained by the preparation method described above, by increasing the first spacing at the light-transmitting opening, light with a larger tilt angle can pass through the light-transmitting opening, thereby increasing the light transmittance of the display panel without affecting the arrangements (area, arrangement density, etc.) of the isolation openings.

In a specific implementation of the second aspect of the present disclosure, an orthographic projection of a surface of the support portion away from the substrate on the substrate is located within an orthographic projection of a surface of the isolation portion close to the substrate on the substrate, and a distance between adjacent edges of the two orthographic projections is the first spacing; and an orthographic projection of the support portion on the substrate is located within an orthographic projection of the isolation portion on the substrate, a distance between adjacent edges of the orthographic projections of the support portion and the isolation portion is defined as a second spacing, and the second spacing located inside the light-transmitting opening is greater than the second spacing located inside the isolation opening.

In a specific implementation of the second aspect of the present disclosure, the step of forming the isolation structure and the light-emitting devices on the substrate may include: after forming the plurality of first electrodes on the substrate, depositing a pixel defining material film layer that covers the first electrodes; forming a first material layer and a second material layer that are sequentially stacked on the pixel defining material film layer, and performing a patterning process on the first material layer and the second material layer to form the support portion and the isolation portion, respectively, and to form the isolation openings and the light-transmitting opening that are enclosed by the support portion and the isolation portion; patterning the pixel defining material film layer to form pixel openings corresponding to the isolation openings; and sequentially depositing and etching a light-emitting functional material layer and a second electrode, respectively, at least twice to form the light-emitting devices at the isolation openings; where the number of etchings on a sidewall of the isolation structure at the light-transmitting opening is greater than the number of etchings on a sidewall of the isolation structure in the isolation opening, the first spacing at the isolation opening is less than the first spacing at the light-transmitting opening, and the second spacing at the isolation opening is less than the second spacing at the light-transmitting opening.

In one embodiment,, the process of forming the isolation structure and the light-emitting devices includes: forming first-type isolation openings and the light-transmitting opening that are enclosed by the support portion and the isolation portion during the process of forming the support portion and the isolation portion; patterning the pixel defining material film layer to form pixel openings corresponding to the first-type isolation openings; sequentially depositing a light-emitting functional material layer and a conductive material layer to cover the isolation structure, the first-type isolation openings and the light-transmitting opening; forming an encapsulation material layer on a side of the conductive material layer away from the substrate, and then performing a patterning process on the light-emitting functional material layer, the conductive material layer and the encapsulation material layer to remove the light-emitting functional material layer, the conductive material layer and the encapsulation material layer outside positions where the first-type isolation openings are located, where the remaining light-emitting functional material layer forms light-emitting functional layers, the remaining conductive material layer forms second electrodes, and the remaining encapsulation material layer forms encapsulation units; and based on the process of forming the first-type isolation openings and the light-emitting devices therein, sequentially forming second-type isolation openings and third-type isolation openings in the isolation structure, forming light-emitting devices in the second-type isolation openings and the third-type isolation openings, respectively, and during patterning processes of forming the second-type isolation openings and the third-type isolation openings, etching the isolation structure on a side where the light-transmitting opening is located, and after the second-type isolation openings and the third-type isolation openings are formed, the first spacing at the isolation opening is less than the first spacing at the light-transmitting opening, and the second spacing at the isolation opening is less than the second spacing at the light-transmitting opening.

In the above embodiments, the light-emitting devices are prepared in batches, and the isolation openings (including the first-type isolation openings, the second-type isolation openings and the third-type isolation openings) corresponding to the light-emitting devices are also prepared in batches. Therefore, only one etching is performed on the isolation structure at each isolation opening, and at least three etchings are performed on the isolation structure at the light-transmitting opening. Thus, the isolation structure may be subjected to greater lateral etching at the light-transmitting opening than at the isolation opening, and the first spacing at the isolation opening is less than the first spacing at the light-transmitting opening.

In another specific implementation of the second aspect of the present disclosure, the step of forming the isolation structure and the light-emitting devices on the substrate may include: after forming the plurality of first electrodes on the substrate, depositing a pixel defining material film layer that covers the first electrodes; forming a first material layer and a second material layer that are sequentially stacked on the pixel defining material film layer, and performing a patterning process on the first material layer and the second material layer to form a bottom portion, a body portion and the isolation portion, respectively, and to form the isolation openings and the light-transmitting opening that are enclosed by the bottom portion, the body portion and the isolation portion, where the bottom portion and the body portion form the support portion; patterning the pixel defining material film layer to form pixel openings corresponding to the isolation openings; and sequentially depositing and etching a light-emitting functional material layer and a second electrode, respectively, at least twice to form the light-emitting devices at the isolation openings; where the number of etchings on a sidewall of the isolation structure at the light-transmitting opening is greater than the number of etchings on a sidewall of the isolation structure in the isolation opening, the first spacing at the isolation opening is less than the first spacing at the light-transmitting opening, and the second spacing at the isolation opening is less than the second spacing at the light-transmitting opening.

In one embodiment,, the process of forming the isolation structure and the light-emitting devices includes: forming first-type isolation openings and the light-transmitting opening that are enclosed by the bottom portion, the body portion and the isolation portion during the process of forming the bottom portion, the body portion and the isolation portion; patterning the pixel defining material film layer to form pixel openings corresponding to the first-type isolation openings; sequentially depositing a light-emitting functional material layer and a conductive material layer to cover the isolation structure, the first-type isolation openings and the light-transmitting opening; forming an encapsulation material layer on a side of the conductive material layer away from the substrate, and then performing a patterning process on the light-emitting functional material layer, the conductive material layer and the encapsulation material layer to remove the light-emitting functional material layer, the conductive material layer and the encapsulation material layer outside positions where the first-type isolation openings are located, where the remaining light-emitting functional material layer forms light-emitting functional layers, the remaining conductive material layer forms second electrodes, and the remaining encapsulation material layer forms encapsulation units; and based on the process of forming the first-type isolation openings and the light-emitting devices therein, sequentially forming second-type isolation openings and third-type isolation openings in the isolation structure, forming light-emitting devices in the second-type isolation openings and the third-type isolation openings, and during patterning processes of forming the second-type isolation openings and the third-type isolation openings, etching the body portion and the bottom portion from the side of the light-transmitting opening, and after the second-type isolation openings and the third-type isolation openings are formed, in the light-transmitting opening, an orthographic projection of an edge of the bottom portion on the substrate coincides with an orthographic projection of the body portion on the substrate, or the orthographic projection of the edge of the bottom portion on the substrate is located within the orthographic projection of the body portion on the substrate, and after the second-type isolation openings and the third-type isolation openings are formed, the first spacing at the isolation opening is less than the first spacing at the light-transmitting opening, and the second spacing at the isolation opening is less than the second spacing at the light-transmitting opening.

In the above embodiments, the light-emitting devices are prepared in batches, and the isolation openings (including the first-type isolation openings, the second-type isolation openings and the third-type isolation openings) corresponding to the light-emitting devices are also prepared in batches. Therefore, only one etching is performed on the isolation structure at each isolation opening, and at least three etchings are performed on the isolation structure at the light-transmitting opening. In addition, the bottom portion may be subjected to greater lateral etching, and the bottom portion is shield by the body portion at the light-transmitting opening. Therefore, with respect to the isolation opening, the first spacing at the isolation opening is much less than the first spacing at the light-transmitting opening, and the second spacing at the isolation opening is much less than the second spacing at the light-transmitting opening.

In a specific implementation of the second aspect of the present disclosure, during the process of forming the second-type isolation openings and the third-type isolation openings, wet etching is used to etch a first conductive material layer for forming the bottom portion, and rates at which the first conductive material layer, a second conductive material layer and a third material layer are etched by an etching material for wet etching decrease in sequence. In this way, during wet etching, the bottom portion formed by the first conductive material layer can be laterally etched to a greater extent than the body portion formed by the second conductive material layer, and the edge of the bottom portion is shielded by the body portion.

A third aspect of the present disclosure provides a display device. The display device includes the display panel as described in the first aspect, or the display panel obtained by the preparation method as described in the second aspect.

### BRIEF DESCRIPTION OF THE DRAWINGS

FIG. 1 is a planar structural schematic diagram of a display panel according to an embodiment of the present disclosure.

FIG. 2 is an enlarged view of a region S1 of the display panel shown in FIG. 1.

FIG. 3A is a sectional view of the display panel shown in FIG. 2 along M1-N1 in one design.

FIG. 3B is a sectional view of the display panel shown in FIG. 2 along M2-N2.

FIG. 3C is an enlarged view of part of an isolation structure located between two isolation openings in the display panel shown in FIG. 3B.

FIG. 3D is an enlarged view of an alternative isolation structure analogous to the isolation structure in the display panel shown in FIG. 3C.

FIG. 4A is a sectional view of the display panel shown in FIG. 2 along M1-N1 in an alternative design.

FIG. 4B is an enlarged view of a region S2 of the display panel shown in FIG. 4A.

FIG. 5A is a sectional view of the display panel shown in FIG. 2 along M1-N1 in an alternative design.

FIG. 5B is an enlarged view of a region S2 of the display panel shown in FIG. 5A.

FIG. 6 is a sectional view of the display panel shown in FIG. 2 along M1-N1 in an alternative design.

FIG. 7 is a flowchart of a preparation method for a display panel according to an embodiment of the present disclosure.

FIGS. 8A-8I are process diagrams of the preparation method for the display panel shown in FIG. 5A.

### LIST OF REFERENCE SIGNS

10 - Display panel; 11 - Active area; 12 - Border area; 100 - Substrate; 210 - Isolation structure; 201 - Light-transmitting opening; 202 - Isolation opening; 202a - First-type isolation opening; 202b - Second-type isolation opening; 203 - Pixel opening; 211 - Support portion; 211a - Body portion; 211b - Bottom portion; 2111 - Second conductive material layer; 2112 - First conductive material layer; 212a - Third material layer; 212 - Isolation portion; 213 - Pixel defining layer; 213a - Pixel defining material layer; 220 - Light-emitting device; 221 - First electrode; 222 - Second electrode; 223 - Light-emitting functional layer; 2231 - First functional layer; 2232 - Light-emitting layer; 2233 - Second functional layer; 300 - Encapsulation structure; 310 - First encapsulation layer; 311 - Encapsulation unit; 310a - Encapsulating material film layer; 320 - Second encapsulation layer; 330 - Third encapsulation layer; 400 - Photoresist pattern.

### DETAILED DESCRIPTION OF THE EMBODIMENTS

The embodiments of the specification will be clearly and completely described below in conjunction with the accompanying drawings in the embodiments of the specification. Apparently, the embodiments described are merely some rather than all of the embodiments of the specification.

In a display product, some functional film layers in light-emitting devices may be formed by means of evaporation. However, since there are various functional film layers in each light-emitting device and some functional film layers (e.g., light-emitting layers) in the light-emitting devices that emit different types of light are made of different materials, it is necessary to perform multiple alignments during evaporation of these functional film layers via masks (e.g., fine masks). In order to solve the problem of position offset caused by the alignment accuracy error, enough space (safety margin related to the alignment error) needs to be reserved between the different light-emitting devices to ensure that the location of the actual light-emitting region of each light-emitting device may have a certain overlap rate with the design location (design area). This actually compresses the design area of the light-emitting region of the light-emitting device, not only limiting the light-emitting area of the light-emitting device, but also preventing a further increase of the arrangement density of the light-emitting devices, and it is difficult to further improve the pixels-per-inch (PPI) of a display panel.

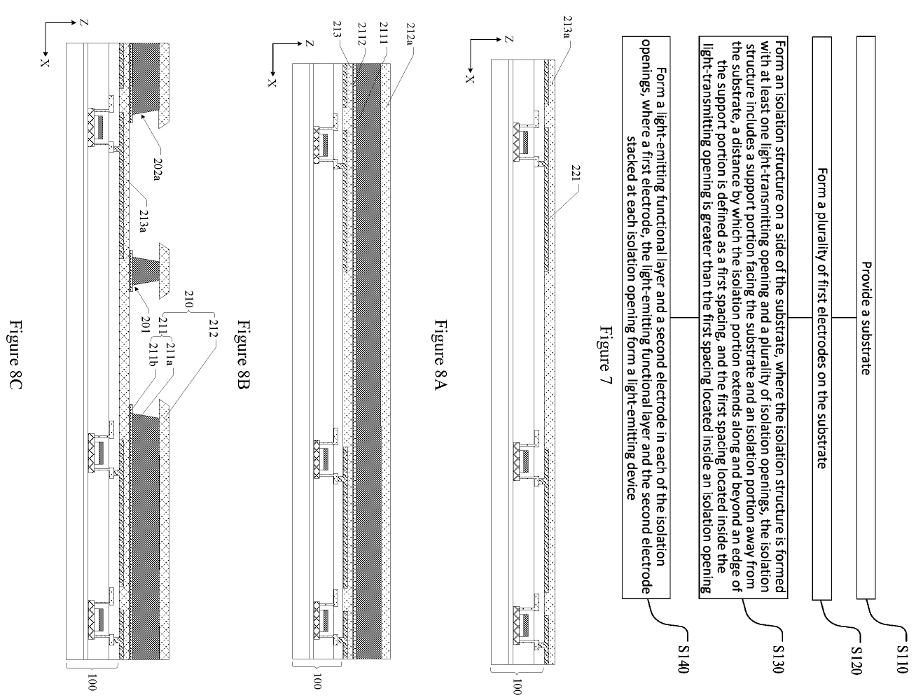

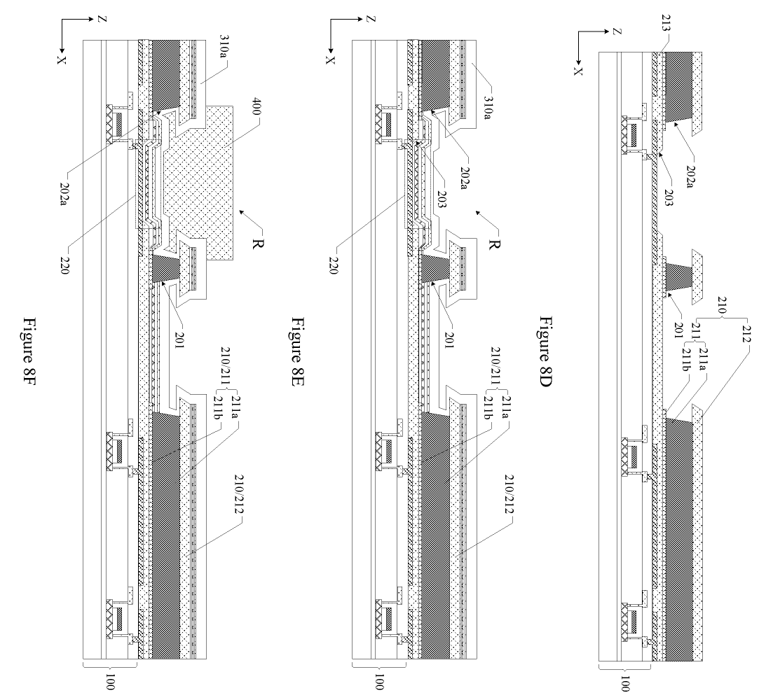

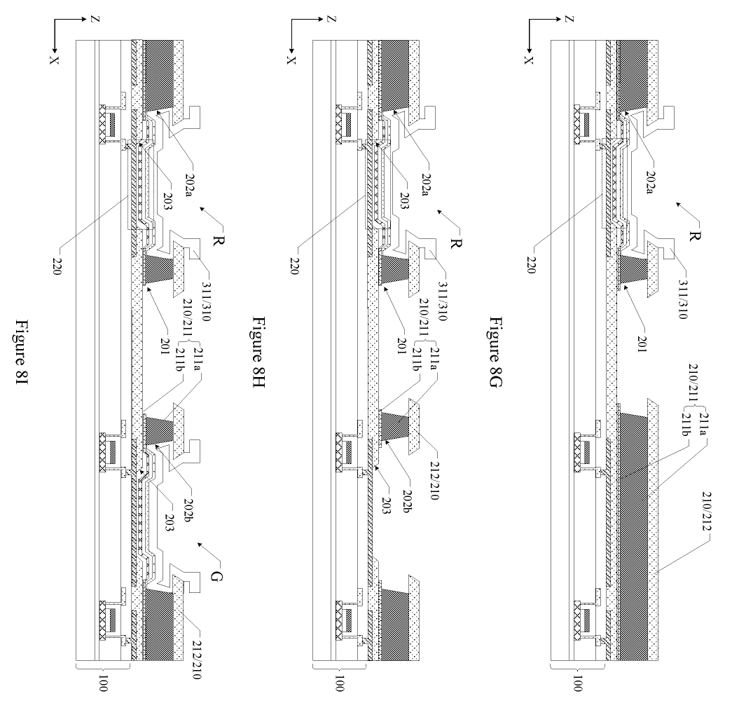

In the present disclosure, the functional film layers of adjacent light-emitting devices are separated by providing the isolation structure at a gap between the light-emitting devices, and in the evaporation process for the functional film layers, it is only necessary to carry out the whole-surface evaporation on the display panel without the need to separately prepare the functional film layers of each light-emitting device by means of a mask. In this process, there is no need to take into account the problem of alignment accuracy during evaporation, and thus the gap between the light-emitting devices can be designed to have a small size so as to increase the PPI (for the principle, reference may be made to the relevant description of the following embodiments related to FIGS. 8A-8I).

In some application scenarios, the display panel needs to have functions such as transparent display and under-display recognition (fingerprint recognition, under-display camera, and infrared sensing) based on application requirements, and a light-transmitting region may be defined in the display panel, and a light-transmitting hole is provided at a gap between sub-pixels of the light-transmitting region to achieve light transmission. However, the isolation structure may block incident light. Therefore, in a region where the light-transmitting hole is located, the isolation structure may limit an angle of the incident light and limit the incident amount of light with a large tilt angle, thereby making it difficult to further improve the light transmittance of the display panel without affecting the PPI and aperture ratio of the display panel.

At least one embodiment of the present disclosure provides a display panel and a preparation method therefor, and a display device to at least solve the above problems. The display panel includes a substrate, and an isolation structure and a plurality of light-emitting devices located on the substrate. The isolation structure defines at least one light-transmitting opening and a plurality of isolation openings, the light-emitting devices are at least partially located inside the isolation openings, the isolation structure includes a support portion and an isolation portion arranged on the support portion, a distance by which the isolation portion extends along and beyond an edge of the support portion is defined as a first spacing, and the first spacing located inside the light-transmitting opening is greater than the first spacing located inside the isolation opening. In the display panel, by increasing the first spacing at the light-transmitting opening, light with a larger tilt angle can pass through the light-transmitting opening, thereby increasing the light transmittance of the display panel without affecting the arrangements (area, arrangement density, etc.) of the isolation openings.

The structure of the display panel according to at least one embodiment of the present disclosure will be described in detail below with reference to the drawings. In addition, in these drawings, a spatial rectangular coordinate system is established with the substrate in the display panel as the reference, to intuitively present positional relationships between elements in the display panel. In this spatial rectangular coordinate system, an X-axis and a Y-axis are parallel to a plane where the substrate is located, and a Z-axis is perpendicular to the plane where the substrate is located.

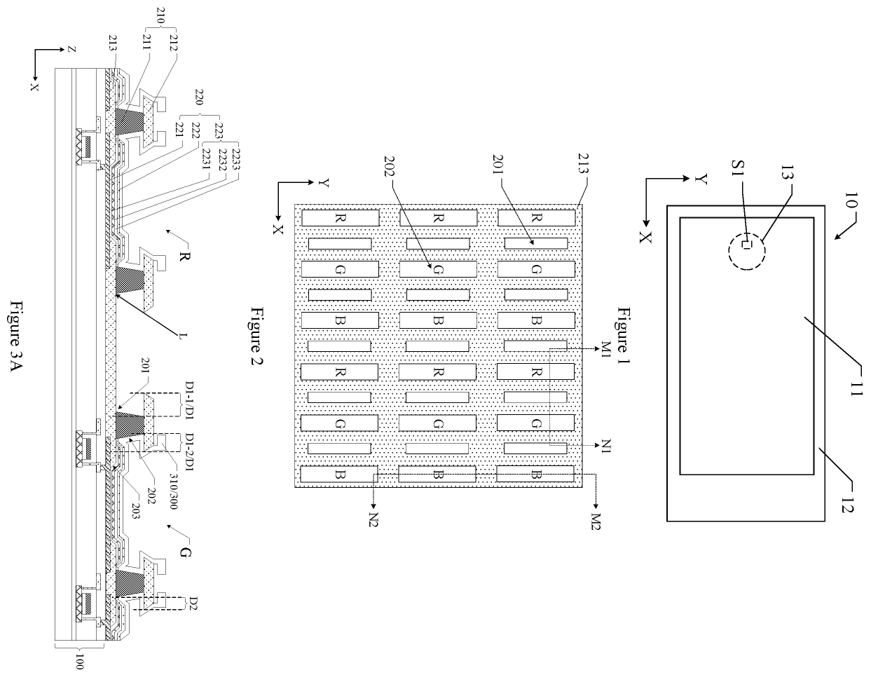

As shown in FIGS. 1, 2, 3A and 3B, the display panel 10 includes an active area 11 and a non-active area 12 surrounding the active area 11, the active area 11 includes a first region 13, and sub-pixels (e.g., R, G and B) that emit different colors of light are arranged in the active area 11. A light-transmitting opening 201 is provided in the first region 13. The provision of the light-transmitting opening 201 enables the first region 13 to have a certain light transmittance for under-display recognition, camera, infrared sensing or transparent display. It should be noted that in some embodiments of the present disclosure, part of traces in the non-active area 12 may be routed into the active area 11, and the non-active area 12 may be designed as a single-sided border.

For example, the physical structure of the display panel 10 includes a substrate 100, and an isolation structure 210 and a plurality of light-emitting devices 220 located on the substrate 100. The light-emitting devices 220 are physical light-emitting structures of sub-pixels (e.g., R, G and B).

For example, the isolation structure 210 defines at least one light-transmitting opening 201 and a plurality of isolation openings 202. The isolation openings 202 are configured to confine the light-emitting devices 220, and the light-transmitting opening 201 is arranged in the first region 13 and is located between the light-emitting devices 220. That is, the light-transmitting opening 201 for light transmission is arranged at a gap between the light-emitting devices 220. The use of the isolation structure 210 enables the preparation process for the light-emitting devices 220 to be performed without a fine mask. Therefore, there is no need to consider the alignment accuracy of the preparation process, which helps to reduce the size of the gap between the light-emitting devices 220 and improve the PPI of the display panel 10 (for the principle, reference may be made to the relevant description of the embodiments shown in FIGS. 8A-8I). In addition, in the first region 13, providing the light-transmitting opening 201 in the isolation structure 210 enables a region of the display panel 10 where the light-transmitting opening 201 is provided to transmit light, thereby allowing the first region 13 of the display panel 10 to realize the function of transparent display or under-display recognition such as fingerprint recognition, under-display camera and infrared sensing.

The isolation structure 210 includes a support portion 211 (lower end) facing the substrate 100 and an isolation portion 212 (upper end) away from the substrate 100, and a distance by which the isolation portion 212 extends from the support portion 211 (a distance by which the isolation portion 212 extends along and beyond an edge of the support portion 211) is defined as a first spacing D1.

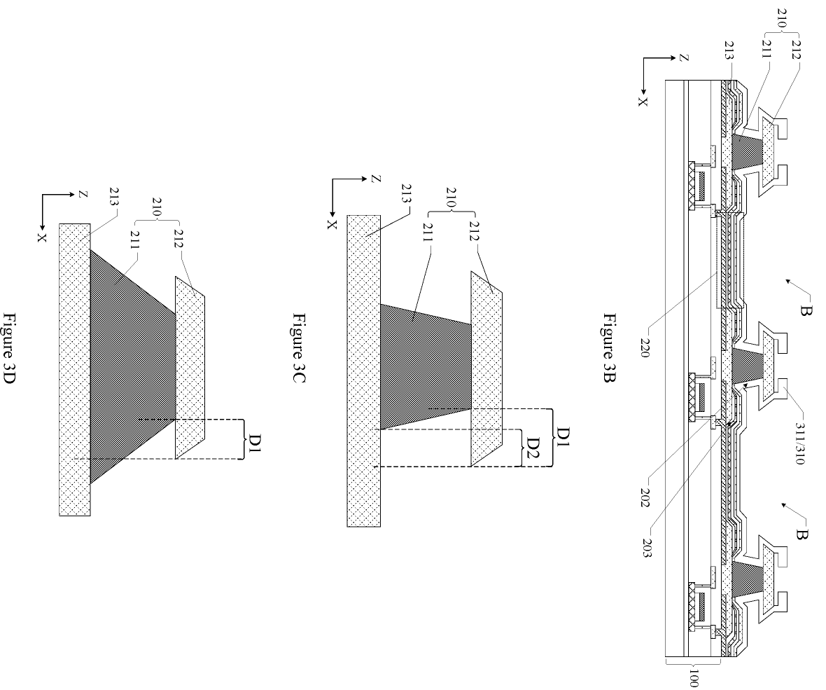

As shown in FIG. 3A, the first spacing D1-1 located at the light-transmitting opening 201 is greater than the first spacing D1-2 located at an isolation opening 202. In this way, an angle of incidence of light L with a large tilt angle can be increased, so as to increase the luminous flux of light incident at the light-transmitting opening 201, thereby increasing the light transmittance of the display panel.

It should be noted that for the composition, preparation, etc. of the isolation structure 210 (which may be referred to as a partition structure or an isolation pillar), reference may also be made to the relevant descriptions in Patents CN118251982A, 202410864269.8, PCT/CN2024/098407, PCT/CN2024/102783, PCT/CN2024/098217, PCT/CN2024/099419, PCT/CN2024/099072, CN117979755A, CN117998900A, CN117062489A, CN117580403A, CN116583155A, CN116669477A, CN117396039A, CN116669480A, CN116600606A and CN117400332A, which will not be repeated herein.

In at least one embodiment of the present disclosure, as shown in FIGS. 3A-3C, a distance between an edge of an orthographic projection of a surface of the support portion 211 on a side facing the isolation portion 212 on the substrate 100 and an edge of an orthographic projection of the isolation portion 212 on the substrate 100 is the first spacing D1.

In the embodiments of the present disclosure, it is only required that the arrangement relationship between the support portion 211 and the isolation portion 212 can achieve the effect of separating film layers. On this basis, there is no further limitation on other arrangement relationships between the two, which can be selected according to actual process requirements. Two arrangement relationships between the support portion 211 and the isolation portion 212 will be described below in different embodiments.

In some embodiments of the present disclosure, as shown in FIGS. 3A-3C, an orthographic projection of the support portion 211 on the substrate 100 is located within the orthographic projection of the isolation portion 212 on the substrate 100, and the isolation structure 210 is presented as a whole in the shape with a wide top and a narrow bottom, so as to improve the effect of the isolation structure 210 separating the film layers of the light-emitting devices 220. In addition, this solution can further reduce the blocking of incident light with a large angle tilt angle by the support portion 211, thereby increasing the luminous flux of the light incident at the light-transmitting opening 201.

In some other embodiments of the present disclosure, as shown in FIG. 3D, an orthographic projection of a surface of the support portion 211 away from the substrate 100 on the substrate 100 is located within the orthographic projection of the isolation portion 212 on the substrate 100, and the orthographic projection of the isolation portion 212 on the substrate 100 is located within an orthographic projection of a surface of the support portion 211 facing the substrate 100 on the substrate 100.

In at least one embodiment of the present disclosure, as shown in FIGS. 3A-3C, an orthographic projection of the support portion 211 on the substrate 100 is located within an orthographic projection of the isolation portion 121 on the substrate 100, a distance between adjacent edges of the two orthographic projections is defined as a second spacing D2, and the second spacing D2 located inside the light-transmitting opening 201 is greater than the second spacing D2 located inside the isolation opening. In this case, the angle of incidence of the light L with a large tilt angle is limited by the edge of the surface of the support portion 211 facing the substrate 100 and the edge of the isolation portion 121. Therefore, the tilt angle of the incident light L can be increased by increasing the second spacing D2 while keeping the height of the isolation structure 210 unchanged, thereby increasing the luminous flux of the light incident at the light-transmitting opening 201.

In at least one embodiment of the present disclosure, as shown in FIGS. 3A and 3B, each light-emitting device 220 includes a first electrode 221, a second electrode 222 and a light-emitting functional layer 223 sequentially stacked on the substrate 100, and the light-emitting functional layer 223 and the second electrode 222 are at least partially located in the corresponding isolation opening 202. For example, the first electrode 221 may be configured as an anode, and the second electrode 222 may be configured as a cathode.

For example, the light-emitting functional layer 223 may include a first common layer 2231, a light-emitting layer 2232 and a second common layer 2233 that are sequentially stacked, and the first common layer 2231, the light-emitting layer 2232 and the second common layer 2233 are sequentially stacked on the first electrode 221. The first common layer 2231 may include a hole injection layer, a hole transport layer, an electron blocking layer, etc. The second common layer 2233 may include an electron injection layer, an electron transport layer, a hole blocking layer, etc. The isolation structure 210 is arranged and first common layers 2231 (main film layers causing current crosstalk) of the light-emitting devices 220 are electrically disconnected from each other.

In at least one embodiment of the present disclosure, as shown in FIGS. 3A and 3B, the isolation structure 210 includes the support portion 211 and the isolation portion 212 that are stacked on the substrate 100, the support portion 211 is located between the isolation portion 212 and the substrate 100, and an orthographic projection of a surface of the support portion 211 away from the substrate 100 on the substrate 100 is located within the orthographic projection of the isolation portion 212 on the substrate 100, that is, the edge of the isolation portion 212 may extend beyond the edge of the support portion 211. In this way, during evaporation of the film layers (e.g., the light-emitting functional layer 223 and the second electrode 222) in the light-emitting device, the range of evaporation of these film layers can be limited by the isolation portion 212, so as to ensure that other film layers (e.g., the second electrode 222) are connected to the isolation structure 210 while part of the film layers (e.g., the light-emitting functional layer described below) are separated by the isolation structure 210. For example, an end of the support portion 211 away from the isolation portion 212 may serve as the support portion as described above, and the isolation portion 212 may serve as the isolation portion as described above.

In at least one embodiment of the present disclosure, as shown in FIGS. 3A and 3B, the support portion 211 is of a conductive structure, and the second electrode 222 is connected to the support portion 211. In this way, the isolation structure 210 connects second electrodes 222 of the light-emitting devices 220 to form a common electrode.

It should be noted that a material of the second electrode 222 may be a metal material. A smaller thickness of the second electrode 222 results in a higher light transmittance, and a higher resistivity. In the case where the second electrode 222 has an extremely small thickness, the second electrode 222 (which is the common electrode in this case) may have an excessively large voltage drop in the absence of the isolation structure 210. In the embodiments of the present disclosure, the second electrode 222 is electrically connected to the conductive support portion 211, which can eliminate the limitation on the thickness of the second electrode 222, and the second electrode 222 may have a smaller thickness to achieve higher light transmittance.

In at least one embodiment of the present disclosure, the support portion 211 may be of a metal conductive structure. Due to high conductivity of the metal material, the voltage drop when driving the second electrode can be reduced. Correspondingly, the metal material may be light-transmissive only when it is extremely thin (e.g., on the order of several tens of nanometers), and the isolation structure 210 needs to have a certain thickness for separating the light-emitting functional layers 223 (the first common layers 2231 included therein). Correspondingly, the support portion 211 of the isolation structure 210 is almost opaque. Therefore, the isolation structure 210 can be made light-transmissive only by providing the light-transmitting opening 201.

In some embodiments of the present disclosure, as shown in FIGS. 3A and 3B, the isolation structure 210 may be of a double-layer structure composed of the support portion 211 and the isolation portion 212, and the support portion 211 is of a single-layer structure.

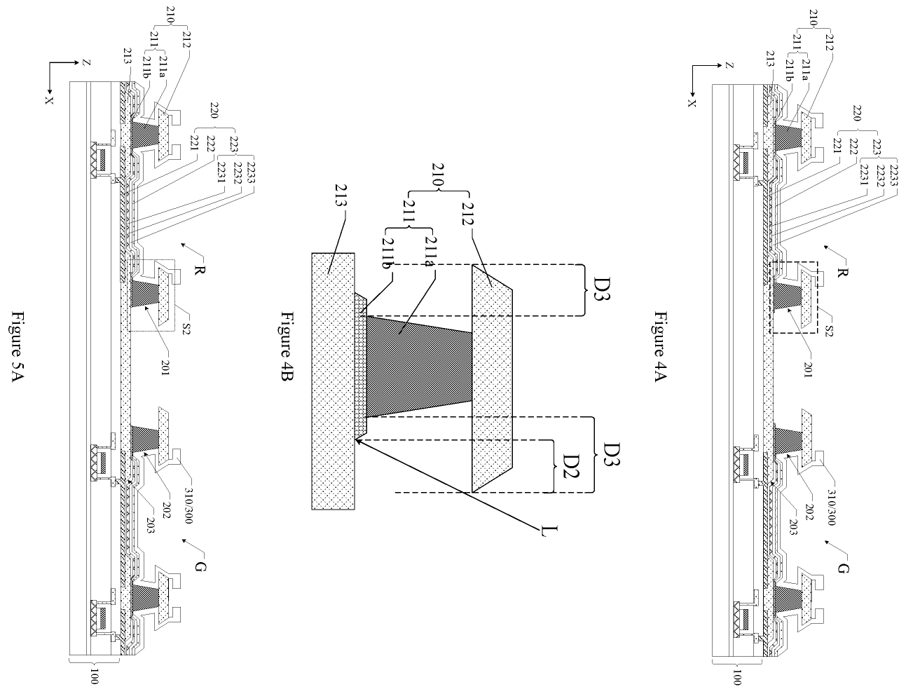

In some other embodiments of the present disclosure, as shown in FIGS. 4A and 4B, the isolation structure 210 is at least of a three-layer structure. For example, the support portion 211 of the isolation structure 210 includes a body portion 211a and a bottom portion 211b, and the bottom portion 211b is located on a side of the body portion 211a away from the isolation portion 212.

For example, an orthographic projection of the bottom portion 211b on the substrate 100 is located within the orthographic projection of the isolation portion 212 on the substrate 100, and an orthographic projection of the body portion 211a on the substrate 100 is located within the orthographic projection of the bottom portion 211b on the substrate 100. For example, the second electrode 222 is connected to a region of a surface of the bottom portion 211b away from the substrate 100 that is not covered by the body portion 211a. For example, the bottom portion 211b is of a conductive structure. In this way, the second electrode 222 is more easily deposited on the bottom portion 211b than on a side surface of the body portion 211a, thereby reducing impedance at the connection of the second electrode 222 and the isolation structure 210.

In the isolation opening 202, a spacing between an orthographic projection of an edge of the bottom portion 211b on the substrate 100 and an orthographic projection of the edge of the isolation portion 212 on the substrate 100 is the second spacing D2.

In some embodiments of the present disclosure, as shown in FIGS. 4A and 4B, the orthographic projection of the bottom portion 211b on the substrate 100 is located within the orthographic projection of the isolation portion 212 on the substrate 100, and the orthographic projection of the body portion on the substrate 100 is located within the orthographic projection of the bottom portion 211b on the substrate 100. In this way, in each of the light-transmitting opening 201 and the isolation opening 202, the spacing between the orthographic projection of the edge of the bottom portion 211b on the substrate 100 and the orthographic projection of the edge of the isolation portion 212 on the substrate 100 is the second spacing D2.

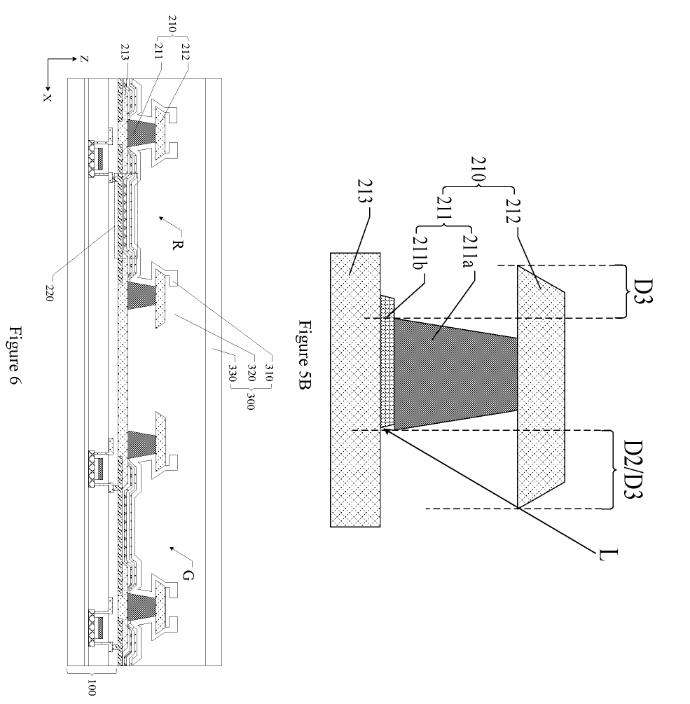

In some other embodiments of the present disclosure, as shown in FIGS. 5A and 5B, in the isolation opening 202, an orthographic projection of an edge of the body portion 211a on the substrate 100 is located within the orthographic projection of the bottom portion 211b on the substrate 100, and the spacing between the orthographic projection of the edge of the bottom portion 211b on the substrate 100 and the orthographic projection of the edge of the isolation portion 212 on the substrate 100 is the second spacing D2. In the light-transmitting opening 201, the orthographic projection of the edge of the bottom portion 211b on the substrate 100 coincides with the orthographic projection of the body portion 211a on the substrate 100 (as shown in FIG. 5B), or the orthographic projection of the edge of the bottom portion 211b on the substrate 100 is located within the orthographic projection of the body portion 211a on the substrate 100, and a spacing between an orthographic projection of an edge of the body portion 211a facing an end of the bottom portion 211b on the substrate 100 and the orthographic projection of the edge of the isolation portion 212 on the substrate 100 is the second spacing. In this way, in the isolation opening 202, the second electrode 222 is more easily deposited on the bottom portion 211b than on the side surface of the body portion 211a, and therefore, the provision of the bottom portion 211b can reduce impedance at the connection of the second electrode 222 and the isolation structure 210. Furthermore, compared with the side of the isolation opening 202, part of the bottom portion 211b that is located on the side of the light-transmitting opening 201 is removed, and the bottom portion 211b may not shield an edge region of the light-transmitting opening 201, thereby increasing the size of the second spacing D2 at the light-transmitting opening 201, and thus further increasing the transmittance of light with a large tilt angle at the light-transmitting opening 201.

It should be noted that the light-emitting devices 220 are prepared in batches. Therefore, in the actual process, when the structure is as shown in FIGS. 5A and 5B, multiple etchings (mainly lateral etching) can be performed on the isolation structure 210 in the light-transmitting opening 201 during the process of preparing each batch of light-emitting devices 220 (including forming the isolation openings 202 corresponding to these light-emitting devices 220), and part of the bottom portion 211b originally present in the light-transmitting opening 201 is etched to form the configurations as shown in FIGS. 5A and 5B.

In an embodiment of the present disclosure, as shown in FIGS. 4B and 5B, in the isolation opening 202, a distance between adjacent edges of the orthographic projections of the body portion 211a and the isolation portion 212 is defined as a third spacing D3. For example, the third spacing D3 located inside the light-transmitting opening 201 is greater than or equal to the third spacing D3 located inside the isolation opening 202. During the process of preparing each batch of light-emitting devices 220 (including forming the isolation openings 202 corresponding to the light-emitting devices 220), multiple etchings (mainly lateral etching) can be performed on the isolation structure 210 in the light-transmitting opening 201, and the extent to which the body portion 211a is laterally etched at the light-transmitting opening 201 is greater than the extent to which the body portion 211a is laterally etched at the isolation opening 202 to form the configurations as shown in FIGS. 4B and 5B.

In at least one embodiment of the present disclosure, materials of the bottom portion 211b, the body portion 211a and the isolation portion 212 have sequentially increasing etch resistance. In this way, the bottom portion 211b at the lowermost layer can be etched during an etching process (for example, wet etching), and the bottom portion 211b is laterally etched at the light-transmitting opening 201, thereby being shielded by the body portion 211a.

For example, the isolation portion 212, the body portion 211a and the bottom portion 211b may be sequentially prepared from titanium, aluminum and molybdenum, and the isolation structure 210 as shown in FIG. 5 can thus be formed. It should be noted that during the process of etching to form the isolation opening and the light-transmitting opening, dry etching (mainly deep etching) may be used first, followed by wet etching (mainly lateral etching), and the edge of the bottom portion 211b may not be shielded by the body portion 211a at the isolation opening, so as to allow the bottom portion 211b to be used for connection to the second electrode 222.

In at least one embodiment of the present disclosure, referring to FIGS. 3A and 3B again, the display panel may further include a pixel defining layer 213, the pixel defining layer 213 is located between the isolation structure 210 and the substrate 100, the pixel defining layer 213 includes a plurality of pixel openings 203 corresponding to the isolation openings 202, and the pixel openings 203 are in communication with the corresponding isolation openings 202. The first electrode 211 is located between the pixel defining layer 213 and the substrate 100, each pixel opening 203 is configured to confine the light-emitting device 220 and to expose the first electrode 221, and the pixel opening 203 corresponds to the isolation opening 202.

In at least one embodiment of the present disclosure, referring to FIGS. 3A and 3B again, the pixel openings 203 correspond to the isolation openings 202 on a one-to-one basis, and an orthographic projection of the light-transmitting opening 203 on the substrate 100 is located within an orthographic projection of the pixel defining layer 213 on the substrate 100. That is, in a region where the light-transmitting opening 203 is located, the pixel defining layer 213 is a continuous film layer. During the process of preparing the light-emitting devices 220 in batches by means of the isolation structure 210, multiple etching processes may be performed. In this way, at the light-transmitting opening 201, the light-transmitting opening 201 may be further etched by the etching processes. By retaining the pixel defining layer 213 here, an underlying structure (e.g., a circuit structure in the substrate 100) can be protected during the etching processes.

In at least one embodiment of the present disclosure, the pixel defining layer 213 may be an inorganic film layer. During the process of preparing the light-emitting devices 220 based on the isolation structure 210, the pixel defining layer 213 does not require a large thickness to accommodate the light-emitting devices 220, thereby facilitating a thin and lightweight design of the display panel. Furthermore, the pixel defining layer 213 as an inorganic film layer may have high bonding strength with the isolation structure 210 and the first electrode 221, so as to reduce the risk of the isolation structure 210 and the first electrode 221 peeling off. In addition, the inorganic film layer has high density, which can block intrusion of water, oxygen and the like more effectively, thereby improving the encapsulation effect of the display panel. Moreover, the pixel defining layer 213 may have a smaller thickness when it is an inorganic layer, and an step difference at an edge of the pixel opening 203 can be reduced, so as to improve the film continuity of the second electrode 222 here and to reduce the impedance of the second electrode 222, thereby ensuring the display effect of the display panel.

In at least one embodiment of the present disclosure, referring to FIGS. 3A and 3B again, the display panel may further include an encapsulation structure 300, the encapsulation structure 300 may include a first encapsulation layer 310, the first encapsulation layer 310 is located on a side of the light-emitting device 220 away from the substrate 100 and includes a plurality of encapsulation units 311 corresponding to the isolation openings 202, and the encapsulation units 311 cover the corresponding isolation openings 202. The light-emitting devices 220 are prepared in batches based on different emission colors, and the encapsulation units 311 are configured to protect the light-emitting devices 220 during the preparation process; therefore, the encapsulation units are also prepared in batches.

For example, referring to FIGS. 3A and 3B again, an edge of an encapsulation unit 311 extends to a side of the isolation structure 210 (e.g., the isolation portion 212 included therein) away from the substrate 100, and part of the encapsulation unit located on the side of the isolation structure 210 (e.g., the isolation portion 212 included therein) away from the substrate 100 is spaced apart from the isolation structure 210 (e.g., the isolation portion 212 included therein) to form a suspended portion. The reason for the formation of the suspended portion is related to the process of preparing the light-emitting devices 200 based on the isolation structure 210. For details, reference may be made to the following relevant descriptions about the embodiments shown in FIGS. 8A-8I, which will not be repeated herein.

In at least one embodiment of the present disclosure, referring to FIGS. 3A and 3B, the plurality of light-emitting devices 220 are classified into multiple types of light-emitting devices that emit different colors of light, and the encapsulation units 311 that respectively correspond to the light-emitting devices 220 that emit different colors of light and are adjacent to each other are spaced apart from each other. The reason for the formation of the first encapsulation layer 310 in this structure is related to the process of preparing the light-emitting devices 200 based on the isolation structure 210. For details, reference may be made to the following relevant descriptions about the embodiments shown in FIGS. 8A-8I, which will not be repeated herein.

In at least one embodiment of the present disclosure, as shown in FIG. 6, the encapsulation structure 300 may further include a second encapsulation layer 320 and a third encapsulation layer 330 that cover the first encapsulation layer 310 and the isolation structure 210, and the second encapsulation layer 320 is located between the first encapsulation layer 310 and the third encapsulation layer 330. For example, the first encapsulation layer 310 and the third encapsulation layer 330 are inorganic layers. The inorganic layers have high density to block water and oxygen. The second encapsulation layer 320 is an organic layer to serve as a planarization layer, and thus has a large thickness to planarize a surface of the display panel, thereby facilitating preparation of functional structures such as a touch structure, an optical film and a cover plate on the encapsulation layer 300.

It should be noted that in the embodiments of the present disclosure, the designed area of the first region is not limited, and can be designed according to requirements of the actual process and the application scenarios of the display panel.

For example, in some embodiments of the present disclosure, the entire active area may be designed as the first region 13. With this design, the display panel can be used in scenarios such as transparent display.

For example, in some other embodiments of the present disclosure, referring to FIG. 1 again, the active area further includes a second region (a region within the active area 11 and outside the first region 13), the second region is located on at least one side of the first region 13, the light-transmitting opening 201 is located in the first region, and the first region has a higher light transmittance than the second region. For example, the first region 13 is a light-transmitting region, and the second region is a non-light-transmitting region. With this design, the display panel can be used in scenarios such as fingerprint recognition or under-display camera.

In at least one embodiment of the present disclosure, as shown in FIG. 6, the substrate 100 may include a base and a drive circuit layer located on the base, the drive circuit layer includes a plurality of pixel drive circuits in the active area, and a display functional layer is located on a side of the drive circuit layer away from the base. For example, each pixel drive circuit may include a plurality of thin film transistors (TFTs), capacitors, etc., which are, for example, formed in a variety of forms such as 2T1C (i.e., two thin film transistors (TFTs) and one capacitor (C)), 3T1C, or 7T1C. The pixel drive circuit is connected to the light-emitting device 220 in the display functional layer to control an on-ff state and the luminous brightness of the light-emitting device 200.

At least one embodiment of the present disclosure provides a preparation method for a display panel. As shown in FIG. 7, reference may be made to steps S110 to S140 below for the specific process of the preparation method.

In S110, a substrate is provided.

In S120, a plurality of first electrodes are formed on the substrate.

In S130, an isolation structure is formed on a side of the substrate, where the isolation structure is formed with at least one light-transmitting opening and a plurality of isolation openings, the isolation structure includes a support portion facing the substrate and an isolation portion away from the substrate, a distance by which the isolation portion extends along and beyond an edge of the support portion is defined as a first spacing, and the first spacing located inside the light-transmitting opening is greater than the first spacing located inside an isolation opening.

In S140, a light-emitting functional layer and a second electrode are formed in each of the isolation openings, where a first electrode, the light-emitting functional layer and the second electrode stacked at each isolation opening form a light-emitting device.

It should be noted that the light-emitting devices are prepared in batches, and the first spacing at the isolation opening is less than the first spacing at the light-transmitting opening after all the light-emitting devices are formed.

In the display panel obtained by the preparation method with the above steps S110 to S140, by increasing the first spacing at the light-transmitting opening, light with a larger tilt angle can pass through the light-transmitting opening, thereby increasing the light transmittance of the display panel without affecting the arrangements (area, arrangement density, etc.) of the isolation openings. The structure of the display panel obtained by the preparation method may be as shown in FIGS. 3A or 3B and for its specific process steps, reference may be made to the following related descriptions about the embodiments shown in FIGS. 8A-8I, which will not be repeated herein.

In the preparation method for a display panel according to at least one embodiment of the present disclosure, an orthographic projection of a surface of the support portion away from the substrate on the substrate is located within an orthographic projection of a surface of the isolation portion close to the substrate on the substrate, and a distance between adjacent edges of the two orthographic projections is the first spacing; and an orthographic projection of the support portion on the substrate is located within an orthographic projection of the isolation portion on the substrate, a distance between adjacent edges of the orthographic projections of the support portion and the isolation portion is defined as a second spacing, and the second spacing located inside the light-transmitting opening is greater than the second spacing located inside the isolation opening. For the structure of the display panel in the preparation method, reference may be made to the related descriptions in the above embodiments, which will not be repeated herein.

It should be noted that during the preparation process of the display panel, as the isolation structure at the light-transmitting opening is etched, the second spacing in the light-transmitting opening can increase while the first spacing in the light-transmitting opening increases.

In some embodiments of the present disclosure, for the structure shown in FIGS. 3A or 3B, in the above process steps S110 to S140, the preparation method for forming the light-emitting devices and the isolation structure may further include: after forming the plurality of first electrodes on the substrate, depositing a pixel defining material film layer that covers the first electrodes; forming a first material layer and a second material layer that are sequentially stacked on the pixel defining material film layer, and performing a patterning process on the first material layer and the second material layer to form the support portion and the isolation portion, respectively, and to form the isolation openings and the light-transmitting opening that are enclosed by the support portion and the isolation portion; patterning the pixel defining material film layer to form pixel openings corresponding to the isolation openings; and sequentially depositing and etching a light-emitting functional material layer and a second electrode, respectively, at least twice to form the light-emitting devices at the isolation openings; where the number of etchings on a sidewall of the isolation structure at the light-transmitting opening is greater than the number of etchings on a sidewall of the isolation structure in the isolation opening, the first spacing at the isolation opening is less than the first spacing at the light-transmitting opening, and the second spacing at the isolation opening is less than the second spacing at the light-transmitting opening.

Specifically, the process may include the following steps S210 to S260.

In S210, after forming the plurality of first electrodes on the substrate, a pixel defining material film layer that covers the first electrodes is deposited.

In S220, a first material layer and a second material layer that are sequentially stacked are formed on the pixel defining material film layer, and a patterning process is performed on the first material layer and the second material layer to form a support portion and an isolation portion, respectively, and to form first-type isolation openings and the light-transmitting opening that are enclosed by the support portion and the isolation portion, that is, the first-type isolation openings and the light-transmitting opening that are enclosed by the support portion and the isolation portion are formed during the process of forming the support portion and the isolation portion.

In S230, the pixel defining material film layer is patterned to form pixel openings corresponding to the isolation openings.

In S240, a light-emitting functional material layer and a conductive material layer are sequentially deposited to cover the isolation structure, the first-type isolation openings and the light-transmitting opening.

In S250, an encapsulation material layer is formed on a side of the conductive material layer away from the substrate, and then a patterning process is performed on the light-emitting functional material layer, the conductive material layer and the encapsulation material layer to remove the light-emitting functional material layer, the conductive material layer and the encapsulation material layer outside positions where the first-type isolation openings are located, where the remaining light-emitting functional material layer forms light-emitting functional layers, the remaining conductive material layer forms second electrodes, and the remaining encapsulation material layer forms encapsulation units.

In S260, based on the process of forming the first-type isolation openings and the light-emitting devices therein, second-type isolation openings and third-type isolation openings are sequentially formed in the isolation structure, light-emitting devices are formed in the second-type isolation openings and the third-type isolation openings, respectively, and during patterning processes of forming the second-type isolation openings and the third-type isolation openings, the isolation structure is etched on a side where the light-transmitting opening is located, and after the second-type isolation openings and the third-type isolation openings are formed, the first spacing at the isolation opening is less than the first spacing at the light-transmitting opening, and the second spacing at the isolation opening is less than the second spacing at the light-transmitting opening.

In the process of the above steps S210 to S260, the light-emitting devices are prepared in batches, and the isolation openings (including the first-type isolation openings, the second-type isolation openings and the third-type isolation openings) corresponding to the light-emitting devices are also prepared in batches. Therefore, only one etching is performed on the isolation structure at each isolation opening, and at least three etchings are performed on the isolation structure at the light-transmitting opening. Thus, the isolation structure may be subjected to greater lateral etching at the light-transmitting opening than at the isolation opening, and the first spacing at the isolation opening is less than the first spacing at the light-transmitting opening, and the second spacing at the isolation opening is less than the second spacing at the light-transmitting opening. The structure of the display panel obtained by the preparation method may be as shown in FIGS. 3A or 3B.

In some embodiments of the present disclosure, for the structure shown in FIGS. 5A or 5B, in the above process steps S110 to S140, the preparation method for forming the light-emitting devices and the isolation structure may further include: after forming the plurality of first electrodes on the substrate, depositing a pixel defining material film layer that covers the first electrodes; forming a first material layer and a second material layer that are sequentially stacked on the pixel defining material film layer, and performing a patterning process on the first material layer and the second material layer to form a bottom portion, a body portion and the isolation portion, respectively, and to form the isolation openings and the light-transmitting opening that are enclosed by the bottom portion, the body portion and the isolation portion, where the bottom portion and the body portion form the support portion; patterning the pixel defining material film layer to form pixel openings corresponding to the isolation openings; and sequentially depositing and etching a light-emitting functional material layer and a second electrode, respectively, at least twice to form the light-emitting devices at the isolation openings; where the number of etchings on a sidewall of the isolation structure at the light-transmitting opening is greater than the number of etchings on a sidewall of the isolation structure in the isolation opening, the first spacing at the isolation opening is less than the first spacing at the light-transmitting opening, and the second spacing at the isolation opening is less than the second spacing at the light-transmitting opening.

Specifically, the process may include the following process steps S310 to S360.

In S310, after forming the plurality of first electrodes on the substrate, a pixel defining material film layer that covers the first electrodes is deposited.

In S320, a first conductive material layer, a second conductive material layer and a third material layer that are sequentially stacked are formed on the pixel defining material film layer, and a patterning process is performed on the first conductive material layer, the second conductive material layer and the third material layer to form a bottom portion, a body portion and the isolation portion, respectively, and to form first-type isolation openings and the light-transmitting opening that are enclosed by the bottom portion, the body portion and the isolation portion, where the bottom portion and the body portion form the support portion. That is, the process of forming the isolation structure and the light-emitting devices includes: forming first-type isolation openings and the light-transmitting opening that are enclosed by the bottom portion, the body portion and the isolation portion during the process of forming the bottom portion, the body portion and the isolation portion.

In S330, the pixel defining material film layer is patterned to form pixel openings corresponding to the first-type isolation openings.

In S340, a light-emitting functional material layer and a conductive material layer are sequentially deposited to cover the isolation structure, the first-type isolation openings and the light-transmitting opening.

In S350, an encapsulation material layer is formed on a side of the conductive material layer away from the substrate, and then a patterning process is performed on the light-emitting functional material layer, the conductive material layer and the encapsulation material layer to remove the light-emitting functional material layer, the conductive material layer and the encapsulation material layer outside positions where the first-type isolation openings are located, where the remaining light-emitting functional material layer forms light-emitting functional layers, the remaining conductive material layer forms second electrodes, and the remaining encapsulation material layer forms encapsulation units.

In S360, based on the process of forming the first-type isolation openings and the light-emitting devices therein, second-type isolation openings and third-type isolation openings are sequentially formed in the isolation structure, light-emitting devices are formed in the second-type isolation openings and the third-type isolation openings, respectively, and during patterning processes of forming the second-type isolation openings and the third-type isolation openings, the body portion and the bottom portion are etched from the side of the light-transmitting opening, and after the second-type isolation openings and the third-type isolation openings are formed, in the light-transmitting opening, an orthographic projection of an edge of the bottom portion on the substrate coincides with an orthographic projection of the body portion on the substrate (as shown in FIG. 5B), or the orthographic projection of the edge of the bottom portion on the substrate is located within the orthographic projection of the body portion on the substrate, and after the second-type isolation openings and the third-type isolation openings are formed, the first spacing at the isolation opening is less than the first spacing at the light-transmitting opening, and the second spacing at the isolation opening is less than the second spacing at the light-transmitting opening.

In the process of the above steps S310 to S360, the light-emitting devices are prepared in batches, and the isolation openings (including the first-type isolation openings, the second-type isolation openings and the third-type isolation openings) corresponding to the light-emitting devices are also prepared in batches. Therefore, only one etching is performed on the isolation structure at each isolation opening, and at least three etchings are performed on the isolation structure at the light-transmitting opening. In addition, the bottom portion may be subjected to greater lateral etching, and the bottom portion is shielded by the body portion at the light-transmitting opening. Therefore, with respect to the isolation opening, the first spacing at the isolation opening is much less than the first spacing at the light-transmitting opening, and the second spacing at the isolation opening is much less than the second spacing at the light-transmitting opening. The structure of the display panel obtained by the preparation method may be as shown in FIGS. 5A or 5B.

In at least one embodiment of the present disclosure, during the process of forming the second-type isolation openings and the third-type isolation openings, wet etching is used to etch the first conductive material layer for forming the bottom portion, and rates at which the first conductive material layer, the second conductive material layer and the third material layer are etched by an etching material for wet etching decrease in sequence. In this way, during wet etching, the bottom portion formed by the first conductive material layer can be laterally etched to a greater extent than the body portion formed by the second conductive material layer, and the edge of the bottom portion is shielded by the body portion. For the details of the process, reference may be made to the following process steps shown in FIGS. 8A-8I.

The preparation process for a display panel shown in FIG. 5A will be described below with reference to FIGS. 8A-8I, so as to intuitively illustrate the principle by which the isolation structure can increase the PPI and the principle of how to increase the light transmittance at the light-transmitting opening.

As shown in FIG. 8A, a substrate 100 is provided and an array of first electrodes 221 are formed on the substrate 100; and a pixel defining material film layer 213a (e.g., an inorganic material film layer) is deposited on the substrate 100 on which the first electrodes are formed.

As shown in FIG. 8B, a first conductive material layer 2112, a second conductive material layer 2111 and a third material layer 212a are sequentially formed on the pixel defining material film layer 213a.

As shown in FIG. 8C, a patterning process is performed on the first conductive material layer 2112, the second conductive material layer 2111 and the third material layer 212a, and the first conductive material layer 2112, the second conductive material layer 2111 and the third material layer 212a form a bottom portion 211b, a body portion 211a and an isolation portion 212, respectively, the bottom portion 211b and the body portion 211a form a support portion 211, the support portion 211 and the isolation portion 212 form an isolation structure 210, and the support portion 211 and the isolation portion 212 enclose a light-transmitting opening 201 and first-type isolation openings 202a.

It should be noted that in the process stage shown in FIG. 8C, in the light-transmitting opening 201 and a first-type isolation opening 202a, spacings between an orthographic projection of an edge of the bottom portion 211b on the substrate 100 and an orthographic projection of an edge of the isolation portion 212 on the substrate 100 are equal.

In the embodiments of the present disclosure, the patterning process may be a photolithographic patterning process, which may include, for example: coating a photoresist on a structural layer to be patterned, exposing the photoresist using a mask, developing the exposed photoresist to obtain a photoresist pattern, etching (in one embodiment, wet or dry etching) the structural layer using the photoresist pattern, and then, in one embodiment, removing the photoresist pattern. It should be noted that when the material of the structural layer (e.g., a photoresist pattern 400 described below) includes the photoresist, the structural layer may be directly exposed by means of the mask to form the desired pattern.

As shown in FIG. 8D, the pixel defining material film layer 213a is patterned to form a pixel defining layer 213 (having a grid-like planar shape), where the pixel defining layer 213 includes pixel openings 203 corresponding to the first-type isolation openings 202a, and the pixel defining layer 213 covers a gap between adjacent first electrodes. In this way, the pixel defining layer 213 has a grid-like planar shape.

As shown in FIG. 8E, a light-emitting functional material layer and a conductive material layer that cover the isolation structure 210, the light-transmitting opening 201 and the first-type isolation openings 202a are evaporated on the substrate 100, where part of the light-emitting functional material layer located in the first-type isolation openings 202a and the light-transmitting opening 201 forms light-emitting functional layers, and part of the conductive material layer located in the isolation openings 202 and the light-transmitting opening 201 forms second electrodes. In this way, a light-emitting device 220 (first-type light-emitting device R) is formed in each of the first-type isolation openings 202a of the isolation structure 210. Since no fine mask is used for evaporation in this process. Therefore, the evaporated materials may also be deposited on the isolation portion 212. For example, the evaporated light-emitting layer functional layer may emit red light (R). That is, in this stage, the light-emitting device 220 (first-type light-emitting device R) that emits red light is formed in each of the light-transmitting opening 201 and the isolation openings 202 of the isolation structure 210. It should be noted that the light-emitting device 220 at the light-transmitting opening 201 lacks a first electrode.

As shown in FIG. 8E, after the first-type light-emitting devices R are formed, an encapsulation material layer 310a is deposited to cover the first-type light-emitting devices R. The encapsulation material layer 310a covers the entire active area in this stage.

As shown in FIG. 8F, a photoresist is formed (e.g., coated) on the encapsulation material layer 310a, and then is subjected to a patterning process to form a photoresist pattern 400. The photoresist pattern 400 covering only the first-type isolation openings 202a (and may also cover regions near the first-type isolation openings 202a).

As shown in FIG. 8G, a surface of the display panel is etched with the photoresist pattern 400 as a mask to remove the encapsulation material layer 310a, the second electrodes, and the light-emitting functional layers that are not covered by the photoresist pattern 700; and then the remaining photoresist pattern 400 is removed. The rest of the encapsulation material layer 310a forms the encapsulation units 311.

As shown in FIG. 8H, the patterning process on the isolation structure 210 is continued to form second-type isolation openings 202b in the isolation structure 210; and a patterning process is then performed on the pixel defining layer 213 to form pixel openings 203 respectively corresponding to the second-type isolation openings 202b. During this process, the isolation structure 210 may be laterally etched at the light-transmitting opening 201, to increase the sizes of the first spacing and the second spacing in the light-transmitting opening 201.

As shown in FIG. 8I, the above processes shown in FIGS. 8E-8H are repeated to form second-type light-emitting devices G at the second-type isolation openings 202b and to form encapsulation units 311 that cover the second-type light-emitting devices G.

The above process steps shown in FIGS. 8E-8H are further repeated to form third-type isolation openings, to form third-type light-emitting devices B in the third-type isolation openings, and to form encapsulation units 311 that cover the third-type light-emitting devices G, thereby obtaining the display panel shown in FIG. 5A. It should be noted that all the encapsulation units 311 jointly form the first encapsulation layer 310.

It should be noted that the order of preparation of the light-emitting devices 220 that emit red light, green light and blue light can be designed according to actual requirements, and will not be limited in the embodiments of the present disclosure.

At least one embodiment of the present disclosure provides a display device, which may include the display panel of the above embodiments. In addition, in the case where the first region is a recognition region, the display device may include a recognition device, and an orthographic projection of the recognition device on the substrate at least partially overlaps with the first region.

For example, in some embodiments of the present disclosure, the recognition device includes at least one fingerprint recognition sensor. For example, the fingerprint recognition sensor may be arranged on a side of the substrate away from the display functional layer, or the fingerprint recognition sensor may be arranged inside the substrate.

For example, in some other embodiments of the present disclosure, the recognition device may be a camera and the camera is located on the side of the substrate away from the display functional layer.

For example, in the embodiments of the present disclosure, the display device may be any product or component having a display function, such as a television, a digital camera, a cell phone, a watch, a tablet computer, a laptop computer and a navigator.

It should be understood that the steps may be reordered, added, or deleted using the various forms of processes illustrated above. For example, the steps recorded in the present disclosure may be performed in parallel, sequentially, or in a different order, provided that the desired results of the embodiments of the present disclosure can be achieved, which are not limited here.

The detailed description of the above embodiments does not constitute a limitation on the scope of protection of the present disclosure. Any modifications, equivalent substitutions, or improvements made within the spirit and principle of the present disclosure should be included within the scope of protection of the present disclosure.

The above descriptions are merely some embodiments of the specification but not intended to limit the specification, and any modifications, equivalent replacements, etc. made within the spirit and principle of the specification should be included within the scope of protection of the specification.

What is claimed is:

1. A display panel, comprising:
a substrate;
an isolation structure located on the substrate and defining at least one light-transmitting opening and a plurality of isolation openings; and
a plurality of light-emitting devices at least partially located inside the isolation openings;
wherein the isolation structure comprises a support portion and an isolation portion arranged on the support portion, a distance by which the isolation portion extends along and beyond an edge of the support portion is defined as a first spacing, and the first spacing located inside the light-transmitting opening is greater than the first spacing located inside an isolation opening.

2. The display panel according to claim 1, wherein an orthographic projection of a surface of the support portion away from the substrate on the substrate is located within an orthographic projection of a surface of the isolation portion close to the substrate on the substrate, and a distance between adjacent edges of the two orthographic projections is the first spacing.

3. The display panel according to claim 2, wherein an orthographic projection of the support portion on the substrate is located within an orthographic projection of the isolation portion on the substrate, a distance between adjacent edges of the orthographic projections of the support portion and the isolation portion is defined as a second spacing, and the second spacing located inside the light-transmitting opening is greater than the second spacing located inside the isolation opening.

4. The display panel according to claim 3, wherein the support portion further comprises a body portion and a bottom portion, the bottom portion being located between the body portion and the substrate.

5. The display panel according to claim 4, wherein an orthographic projection of the bottom portion on the substrate is located within the orthographic projection of the isolation portion on the substrate, an orthographic projection of the body portion on the substrate is located within the orthographic projection of the bottom portion on the substrate, and in the isolation opening, a spacing between an orthographic projection of an edge of the bottom portion on the substrate and an orthographic projection of an edge of the isolation portion on the substrate is the second spacing, a distance between adjacent edges of the orthographic projections of the body portion and the isolation portion is defined as a third spacing, and the third spacing located inside the light-transmitting opening is greater than or equal to the third spacing located inside the isolation opening.

6. The display panel according to claim 4, wherein materials of the bottom portion, the body portion and the isolation portion have sequentially increasing etch resistance.

7. The display panel according to claim 2, wherein each light-emitting device comprises a first electrode, a light-emitting functional layer and a second electrode sequentially stacked on the substrate, the light-emitting functional layer and the second electrode being at least partially located in the corresponding isolation opening.

8. The display panel according to claim 7, wherein the support portion is of a conductive structure, and the second electrode is connected to the support portion.

9. The display panel according to claim 7, further comprising a pixel defining layer, wherein the pixel defining layer is located between the isolation structure and the substrate, the pixel defining layer comprises a plurality of pixel openings corresponding to the isolation openings, and the pixel openings are in communication with the corresponding isolation openings; and
the first electrode is located between the pixel defining layer and the substrate, and each pixel opening confines the light-emitting device and exposes the first electrode.

10. The display panel according to claim 9, wherein the pixel openings correspond to the isolation openings on a one-to-one basis, and an orthographic projection of the light-transmitting opening on the substrate is located within an orthographic projection of the pixel defining layer on the substrate.

11. The display panel according to claim 1, further comprising a first encapsulation layer, wherein the first encapsulation layer is located on a side of a light-emitting device away from the substrate and comprises a plurality of encapsulation units corresponding to the isolation openings on a one-to-one basis, and the encapsulation units cover the corresponding isolation openings.

12. The display panel according to claim 11, wherein an edge of an encapsulation unit extends to a side of the isolation structure away from the substrate, and part of the encapsulation unit located on the side of the isolation structure away from the substrate is spaced apart from the isolation structure to form a suspended portion.

13. The display panel according to claim 11, wherein the plurality of light-emitting devices are classified into multiple types of light-emitting devices that emit different colors of light, and
the encapsulation units that respectively correspond to the light-emitting devices that emit different colors of light and are adjacent to each other are spaced apart from each other.

14. The display panel according to claim 11, further comprising a second encapsulation layer and a third encapsulation layer that cover the first encapsulation layer and the isolation structure, wherein the second encapsulation layer is located between the first encapsulation layer and the third encapsulation layer.

15. The display panel according to claim 1, further comprising an active area, wherein the active area comprises a first region and a second region, the second region is located on at least one side of the first region, the first region has a higher light transmittance than the second region, and the light-transmitting opening is located in the first region.

16. A preparation method for a display panel, comprising:
providing a substrate;
forming a plurality of first electrodes on the substrate;
forming an isolation structure on a side of the substrate, wherein the isolation structure is formed with at least one light-transmitting opening and a plurality of isolation openings, the isolation structure comprises a support portion facing the substrate and an isolation portion away from the substrate, a distance by which the isolation portion extends along and beyond an edge of the support portion is defined as a first spacing, and the first spacing located inside the light-transmitting opening is greater than the first spacing located inside an isolation opening; and
forming a light-emitting functional layer and a second electrode in each of the isolation openings, wherein a first electrode, the light-emitting functional layer and the second electrode stacked at each isolation opening form a light-emitting device;
wherein the first spacing at the isolation opening is less than the first spacing at the light-transmitting opening after all the light-emitting devices are formed.

17. The preparation method according to claim 16, wherein an orthographic projection of a surface of the support portion away from the substrate on the substrate is located within an orthographic projection of a surface of the isolation portion close to the substrate on the substrate, and a distance between adjacent edges of the two orthographic projections is the first spacing,
an orthographic projection of the support portion on the substrate is located within an orthographic projection of the isolation portion on the substrate, a distance between adjacent edges of the orthographic projections of the support portion and the isolation portion is defined as a second spacing, and the second spacing located inside the light-transmitting opening is greater than the second spacing located inside the isolation opening.

18. The preparation method according to claim 17 , wherein the step of forming the isolation structure and the light-emitting devices on the substrate comprises:
after forming the plurality of first electrodes on the substrate, depositing a pixel defining material film layer that covers the first electrodes;
forming a first material layer and a second material layer that are sequentially stacked on the pixel defining material film layer, and performing a patterning process on the first material layer and the second material layer to form the support portion and the isolation portion, respectively, and to form the isolation openings and the light-transmitting opening that are enclosed by the support portion and the isolation portion;
patterning the pixel defining material film layer to form pixel openings corresponding to the isolation openings; and
sequentially depositing and etching a light-emitting functional material layer and a second electrode, respectively, at least twice to form the light-emitting devices at the isolation openings;
wherein the number of etchings on a sidewall of the isolation structure at the light-transmitting opening is greater than the number of etchings on a sidewall of the isolation structure in the isolation opening, the first spacing at the isolation opening is less than the first spacing at the light-transmitting opening, and the second spacing at the isolation opening is less than the second spacing at the light-transmitting opening.

19. The preparation method according to claim 17, wherein the step of forming the isolation structure and the light-emitting devices on the substrate comprises:
after forming the plurality of first electrodes on the substrate, depositing a pixel defining material film layer that covers the first electrodes;
forming a first material layer and a second material layer that are sequentially stacked on the pixel defining material film layer, and performing a patterning process on the first material layer and the second material layer to form a bottom portion, a body portion and the isolation portion, respectively, and to form the isolation openings and the light-transmitting opening that are enclosed by the bottom portion, the body portion and the isolation portion, wherein the bottom portion and the body portion form the support portion;
patterning the pixel defining material film layer to form pixel openings corresponding to the isolation openings; and
sequentially depositing and etching a light-emitting functional material layer and a second electrode, respectively, at least twice to form the light-emitting devices at the isolation openings;
wherein the number of etchings on a sidewall of the isolation structure at the light-transmitting opening is greater than the number of etchings on a sidewall of the isolation structure in the isolation opening, the first spacing at the isolation opening is less than the first spacing at the light-transmitting opening, and the second spacing at the isolation opening is less than the second spacing at the light-transmitting opening.

20. A display device, comprising:
a display panel comprising:
a substrate;
an isolation structure located on the substrate and defining at least one light-transmitting opening and a plurality of isolation openings; and
a plurality of light-emitting devices at least partially located inside the isolation openings;
wherein the isolation structure comprises a support portion and an isolation portion arranged on the support portion, a distance by which the isolation portion extends along and beyond an edge of the support portion is defined as a first spacing, and the first spacing located inside the light-transmitting opening is greater than the first spacing located inside an isolation opening.
